(19) United States
(12) Patent Application Publication
(10) Pub. No.: US 2022/0189900 A1
(43) Pub. Date: Jun. 16, 2022

(54) ELECTRONIC PACKAGE AND FABRICATION METHOD THEREOF

(71) Applicant: SILICONWARE PRECISION INDUSTRIES CO., LTD., Taichung City (TW)

(72) Inventors: Chia-Yu Kuo, Taichung City (TW); Rui-Feng Tai, Taichung City (TW); Yih-Jenn Jiang, Taichung City (TW); Don-Son Jiang, Taichung City (TW); Chang-Fu Lin, Taichung City (TW)

(73) Assignee: SILICONWARE PRECISION INDUSTRIES CO., LTD., Taichung City (TW)

(21) Appl. No.: 17/171,764

(22) Filed: Feb. 9, 2021

(30) Foreign Application Priority Data
Dec. 11, 2020 (TW) 109143885

(51) Int. Cl. H01L 23/00; H01L 23/31; H01L 23/538; H01L 21/48; H01L 21/56

(52) U.S. Cl. CPC H01L 24/20; H01L 23/3128; H01L 23/5386; H01L 2224/214; H01L 21/4853; H01L 21/565; H01L 24/19

(57) ABSTRACT

An electronic package is provided and includes at least one conductor with a relatively large width formed on an electrode pad of an electronic element and in contact with a circuit layer. As such, when the electronic element and the circuit layer deviate in position relative to one another, the circuit layer will be still in contact with the conductor and hence electrically connected to the electronic element.

### BACKGROUND

### 1. Technical Field

The present disclosure relates to semiconductor structures, and more particularly, to an electronic package and a fabrication method thereof.

### 2. Description of Related Art

Along with the progress of semiconductor technologies, various package types have been developed for semiconductor products. To obtain much lighter, thinner, shorter and smaller semiconductor packages, chip scale packages (CSPs) are developed, which are characterized in that the package size is equal to or slightly larger than the size of a chip.

FIGS. 1A to 1D are schematic cross-sectional views showing a method for fabricating a semiconductor package 1 according to the prior art.

Referring to FIG. 1A, a first carrier 10a having a first adhesive layer 100a is provided, at least one semiconductor element 11 is disposed on the first adhesive layer 100a, and an encapsulant 12 is formed by molding to cover the semiconductor element 11. The semiconductor element 11 has an active surface 11a with a plurality of electrode pads 110 and an inactive surface 11b opposite to the active surface 11a, and the semiconductor element 11 is bonded to the first adhesive layer 100a via the active surface 11a thereof.

Referring to FIG. 1B, the encapsulant 12 is partially removed by grinding so as to expose the inactive surface 11b of the semiconductor element 11 from a second surface 12b of the encapsulant 12. Then, a second carrier 10b having a second adhesive layer 100b is disposed on the second surface 12b of the encapsulant 12. Thereafter, the first carrier 10a and the first adhesive layer 100a are removed to expose the first surface 12a of the encapsulant 12.

Referring to FIG. 1C, a redistribution layer (RDL) 13 is formed on the first surface 12a of the encapsulant 12 and the active surface 11a of the semiconductor element 11, and the redistribution layer 13 has a plurality of pad portions 130 electrically connected to the electrode pads 110 of the semiconductor element 11.

Referring to FIG. 1D, the second adhesive layer 100b and the second carrier 10b are removed and then a singulation process is performed. Further, an under bump metallurgy (UBM) layer 15 can be formed on the redistribution layer 13 for mounting a plurality of conductive elements 17 such as solder balls. The UBM layer 15 has an adhesive layer bonded to the redistribution layer 13, a wetting layer bonded to the adhesive layer and a protection layer bonded to the wetting layer. Therein, the adhesive layer is made of titanium (Ti), chromium (Cr) or titanium tungsten (TiW), the wetting layer is made of nickel (Ni) or copper (Cu), and the protection layer is made of a low-resistance metal such as gold (Au) or Cu.

However, during fabrication of the semiconductor package 1, the redistribution layer 13 and the semiconductor element 11 may deviate in position relative to one another due to a precision problem. For example, in the process of FIG. 1A, the encapsulant 12 may press against and displace the semiconductor element 11. Further, in the process of FIG. 1C, deviation may occur in exposure and development of a patterned photoresist used for fabricating the redistribution layer 13 and consequently the pad portions 130 of the redistribution layer 13 cannot come into contact with the electrode pads 110 of the semiconductor element 11, as shown in FIG. 1C′, thus resulting in a problem of poor electrical connection.

Therefore, how to overcome the above-described drawbacks of the prior art has become an urgent issue in the art.

### SUMMARY

In view of the above-described drawbacks of the prior art, the present disclosure provides an electronic package, which comprises: an encapsulant; an electronic element embedded in the encapsulant and having a plurality of electrode pads; at least a conductor formed on and electrically connected to at least one of the electrode pads, wherein the conductor has a metal structure; and a circuit layer formed on the encapsulant and in contact with the conductor.

The present disclosure further provides a method for fabricating an electronic package, which comprises the steps of: providing at least one electronic element having a plurality of electrode pads; encapsulating the electronic element with an encapsulant and forming at least one conductor on at least one of the electrode pads, wherein the conductor has a metal structure and is electrically connected to the electrode pad; and forming a circuit layer on the encapsulant, wherein the circuit layer is in contact with the conductor.

In the above-described electronic package and fabrication method thereof, the electronic element has a passivation layer having a plurality of open regions exposing the electrode pads. For example, a distance between an outermost edge of a layout area of the conductor and an edge of the corresponding open region is greater than or equal to 10 μm.

In the above-described electronic package and fabrication method thereof, a layout area of the conductor is greater than that of the electrode pad.

In the above-described electronic package and fabrication method thereof, the conductor comprises a plurality of metal layers.

In the above-described electronic package and fabrication method thereof, a layout area of the circuit layer is greater than that of the conductor.

In the above-described electronic package and fabrication method thereof, forming the conductor comprises: forming the conductor on the electrode pad first and then simultaneously encapsulating the electronic element and the conductor with the encapsulant so as to bury the conductor in the encapsulant.

In the above-described electronic package and fabrication method thereof, forming the conductor comprises: forming a dielectric layer on the encapsulant; forming an opening in the dielectric layer for exposing the electrode pad; and forming the conductor in the opening, wherein the conductor is in contact with the electrode pad and the conductor is buried in the dielectric layer. For example, the opening has a width greater than that of the electrode pad.

In the above-described electronic package and fabrication method thereof, the circuit layer and the conductor are integrally formed.

The above-described electronic package and fabrication method thereof further comprise forming a plurality of conductive elements on the circuit layer, wherein the conductive elements are electrically connected to the circuit layer.

The above-described electronic package and fabrication method thereof further comprise forming a circuit structure on the encapsulant and the circuit layer, wherein the circuit structure is electrically connected to the circuit layer.

Therefore, in the electronic package and fabrication method thereof according to the present disclosure, through the design of the conductor, when the electronic element and the circuit layer deviate in position relative to one another, the circuit layer will be still in contact with the conductor and hence electrically connected to the electronic element. Compared with the prior art, the present disclosure prevents the problem of poor electrical connection due to deviation of the electronic element, thereby preventing final product failure or scrapping.

### BRIEF DESCRIPTION OF THE DRAWINGS

FIGS. 1A to 1D are schematic cross-sectional views showing a method for fabricating a semiconductor package according to the prior art.

FIG. 1C′ is a schematic partial upper plan view of FIG. 1C.

FIGS. 2A to 2G are schematic cross-sectional views illustrating a method for fabricating an electronic package according to a first embodiment of the present disclosure.

FIG. 2E′ is a schematic partially enlarged view of FIG. 2E.

FIG. 2F′ is a schematic partial upper plan view of FIG. 2E

FIG. 2G′ is a schematic cross-sectional view showing another embodiment of FIG. 2G.

FIGS. 3A to 3C are schematic cross-sectional views illustrating a method for fabricating an electronic package according to a second embodiment of the present disclosure.

FIGS. 4A and 4B are schematic cross-sectional views illustrating a method for fabricating an electronic package according to a third embodiment of the present disclosure.

FIG. 4A′ is a schematic partial upper plan view of FIG. 4A.

FIG. 4C is a schematic partial upper plan view showing an aspect of FIG. 4B.

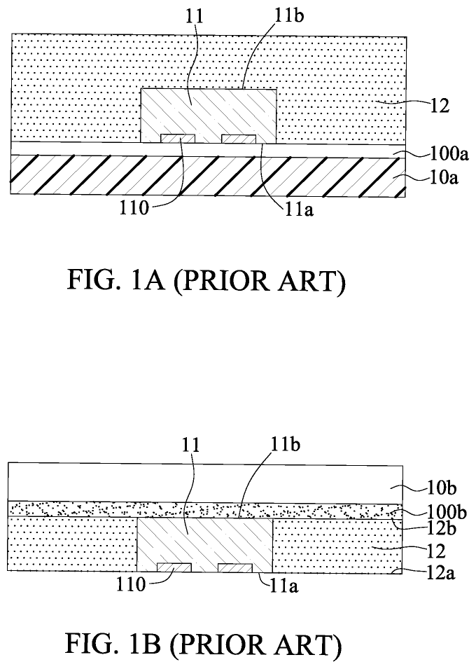

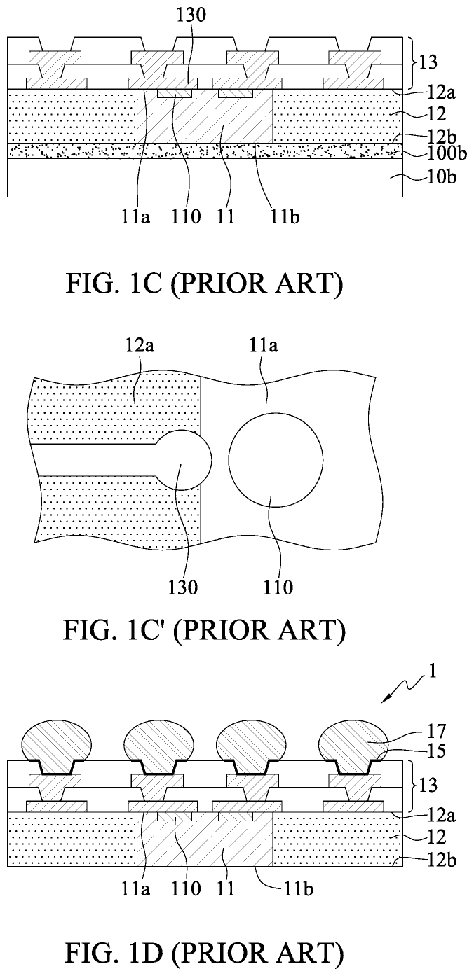

### DETAILED DESCRIPTION

The following illustrative embodiments are provided to illustrate the present disclosure, these and other advantages and effects can be apparent to those skilled in the art after reading this specification.

It should be noted that all the drawings are not intended to limit the present disclosure. Various modifications and variations can be made without departing from the spirit of the present disclosure. Further, terms such as “first,” “second,” “on,” “a,” etc., are merely for illustrative purposes and should not be construed to limit the scope of the present disclosure.

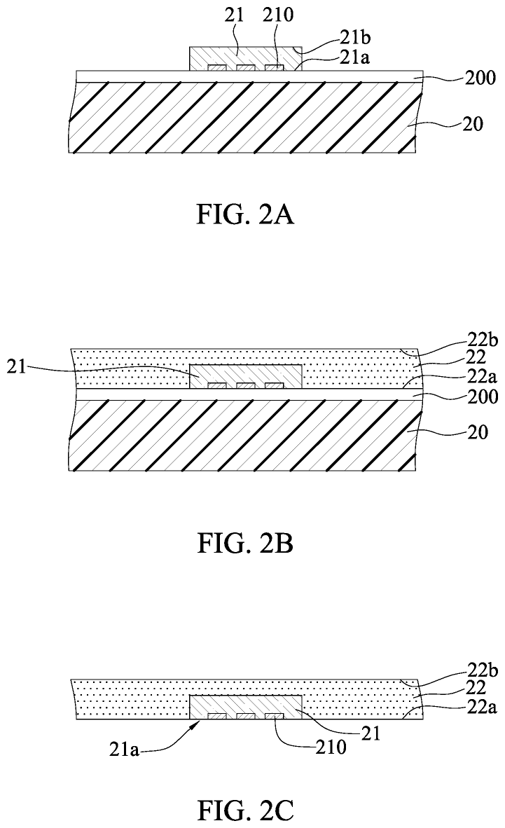

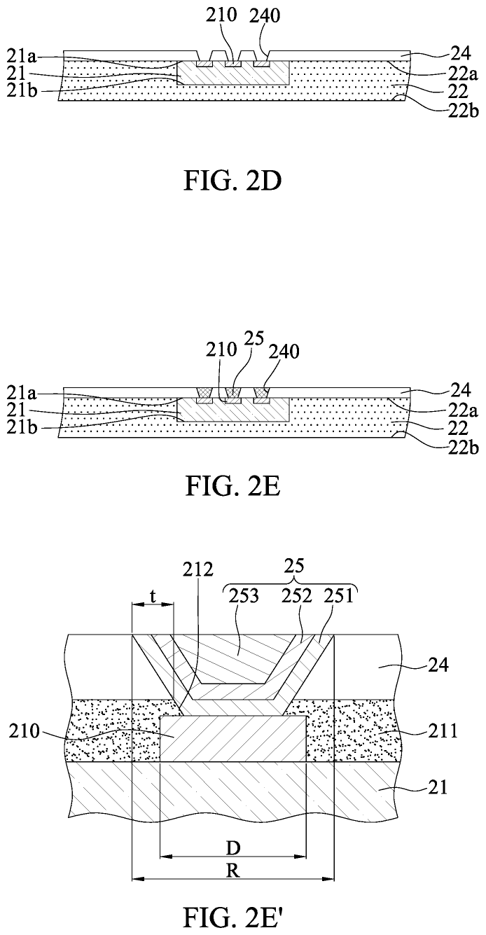

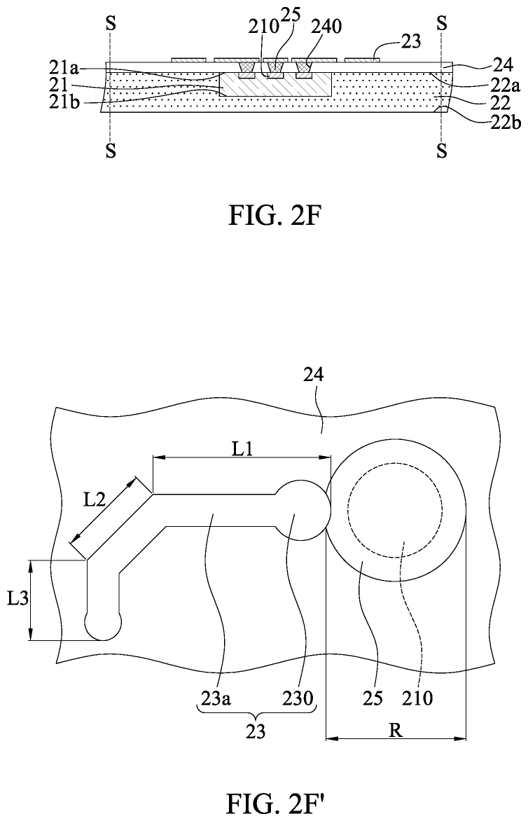

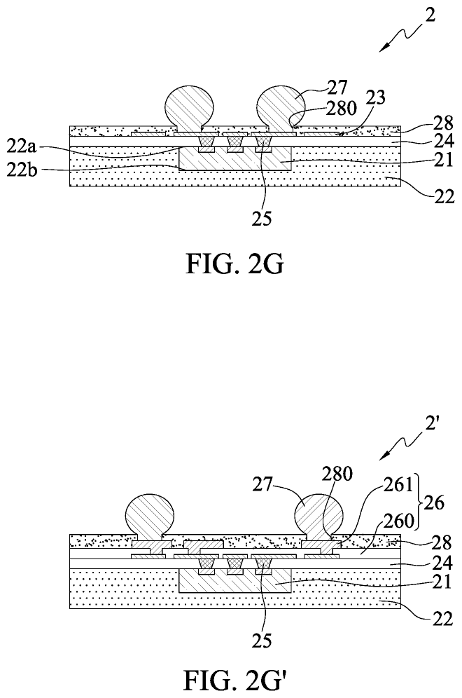

FIGS. 2A to 2G are schematic cross-sectional views illustrating a method for fabricating an electronic package 2 according to a first embodiment of the present disclosure.

Referring to FIG. 2A, at least one electronic element 21 is disposed on a carrier 20.

In an embodiment, the electronic element 21 is an active element such as a semiconductor chip, a passive element such as a resistor, a capacitor or an inductor, or a combination thereof. For example, the electronic element 21 is a semiconductor chip, which has an active surface 21a with a plurality of electrode pads 210 and an inactive surface 21b opposite to the active surface 21a. The electronic element 21 is disposed on the carrier 20 via the active surface 21a thereof.

Further, referring to FIG. 2E′, a passivation layer 211 made of such as silicon nitride (SiN) can be formed on the active surface 21a of the electronic element 21 and have a plurality of open regions 212 exposing the electrode pads 210. For example, the passivation layer 211 covers a portion of the surface of each of the electrode pads 210. But in other embodiments, the surface of the passivation layer 211 can be flush with the surface of the electrode pad 210. It should be understood that there are many kinds of materials and configurations of the passivation layer, and the present disclosure is not limited to as such.

Furthermore, the carrier 20 can be, for example, a board made of a semiconductor material (e.g., silicon or glass), and a release layer 200 (or an adhesive layer) can be formed as needed on the carrier 20 for bonding with the active surface 21a of the electronic element 21.

Referring to FIG. 2B, an encapsulant 22 is formed on the carrier 20 to encapsulate the electronic element 21.

In an embodiment, the encapsulant 22 has a first surface 22a bonded to the release layer 200 and a second surface 22b opposite to the first surface 22a. For example, the encapsulant 22 is made of an insulating material, such as an epoxy resin, and formed on the carrier 20 by lamination or molding.

Furthermore, in other embodiments (not shown), through a leveling process, the second surface 22b of the encapsulant 22 is flush with the inactive surface 21b of the electronic element 21. For example, the leveling process removes a portion of the electronic element 21 and a portion of the encapsulant 22 by grinding.

Referring to FIG. 2C, the carrier 20 and the release layer 200 are removed to expose the active surface 21a of the electronic element 21 and the first surface 22a of the encapsulant 22. The first surface 22a of the encapsulant 22 is flush with the active surface 21a of the electronic element 21.

Referring to FIG. 2D, a dielectric layer 24 is formed on the first surface 22a of the encapsulant 22 and the active surface 21a (or the passivation layer 211) of the electronic element 21, and a plurality of openings 240 are formed in the dielectric layer 24 for exposing the electrode pads 210, respectively.

In an embodiment, each of the openings 240 can have a uniform or variable width (for example, have a cone shape or other suitable shapes).

Referring to FIG. 2E, a plurality of conductors 25 are formed in the openings 240 and electrically connected to the electrode pads 210.

In an embodiment, each of the conductors 25 has a metal structure, which comprises at least one metal layer made of such as Ti, Cr, TiW, Ni, Cu, Au or a combination thereof. For example, referring to FIG. 2E′, the conductor 25 has a UBM structure, which comprises a first metal layer 251 bonded to the corresponding electrode pad 210, a second metal layer 252 bonded to the first metal layer 251, and a third metal layer 253 bonded to the second metal layer 252. The first metal layer 251 is made of Ti, Cr or TiW, the second metal layer 252 is made of Ni or Cu, and the third metal layer 253 is made of Au or Cu. It should be understood that the UBM structure can be various. For example, the UBM structure can be a single metal layer, but the present disclosure is not limited to as such.

Further, the layout area (for example, width R) of the conductor 25 is greater than the layout area (for example, width D) of the electrode pad 210. For example, referring to FIG. 2E′, the distance t between the outermost edge of the layout area of the conductor 25 and the edge of the corresponding open region 212 of the passivation layer 211 is greater than or equal to 10 μm (i.e., t≥10 μm). Preferably, the distance t is 12 μm.

Referring to FIG. 2F, a redistribution layer (RDL) process is performed on the dielectric layer 24 so as to form a circuit layer 23 on the dielectric layer 24.

In an embodiment, referring to FIG. 2F′, the circuit layer 23 is formed by copper electroplating and comprises a plurality of conductive traces 23a and a plurality of conductive pads 230 arranged at one ends of the conductive traces 23a and in contact with the conductors 25 so as to be electrically connected to the electrode pads 210.

Furthermore, the layout area of the circuit layer 23 (e.g., referring to FIG. 2F′, the length L of the conductive trace 23a containing the two ends thereof is the sum of the lengths L1, L2, L3 of the three segments, i.e., L=L1+L2+L3) is greater than the layout area (e.g., width R) of the conductors 25.

Referring to FIG. 2G, an insulating protection layer 28 is formed on the dielectric layer 24 and the circuit layer 23, and a plurality of openings 280 are formed in the insulating protection layer 28 so as to expose portions of the circuit layer 23. Further, a plurality of conductive elements 27 such as solder balls are mounted on the exposed portions of the circuit layer 23.

In an embodiment, a singulation process can be performed along a cutting path S of FIG. 2F so as to obtain the electronic package 2. Subsequently, an electronic device such as a circuit board (not shown) can be mounted on the electronic package 2 through the conductive elements 27.

Moreover, in another embodiment, referring to an electronic package 2′ of FIG. 2G′, if needed, a circuit structure 26 can be formed on the dielectric layer 24 and the circuit layer 23 and electrically connected to the circuit layer 23. For example, the circuit structure 26 comprises at least one insulating layer 260 and a redistribution layer 261 formed on the insulating layer 260. The insulating protection layer 28 is formed on the outermost insulating layer 260 and the conductive elements 27 are formed on and electrically connected to the outermost redistribution layer 261. The redistribution layer 261 is made of copper, and the insulating layer 260 is made of polybenzoxazole (PBO), polyimide (PI), prepreg (PP) or other dielectric materials.

According to the method of the present disclosure, the conductors 25 with a relatively large width R are formed on the electrode pads 210 of the electronic element 21 first and then the circuit layer 23 is formed. As such, when the electronic element 21 and the circuit layer 23 deviate in position relative to one another, the conductive pads 230 of the circuit layer 23 will be still in contact with the conductors 25 and electrically connected to the electronic element 21. Compared with the prior art, the present disclosure can prevent the problem of poor electrical connection of the electronic package 2, 2′ due to deviation of the electronic element 21 (i.e., poor electrical connection between the circuit layer 23 and the electrode pads 210 of the electronic element 21), thus preventing final product failure or scrapping.

Further, by controlling the layout area (or width R) of the conductors 25 (for example, the distance t is greater than or equal to 10 μm, preferably, t=12 μm), the present disclosure can also prevent the problem of poor electrical connection due to deviation (e.g., shift) of the electronic element 21.

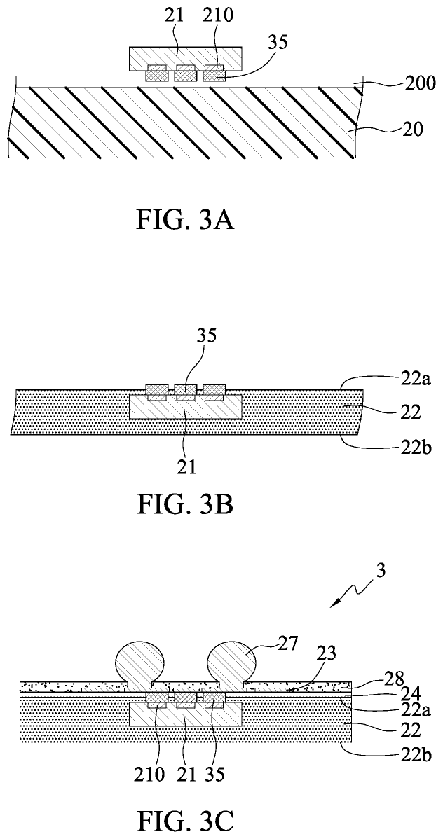

FIGS. 3A to 3C are schematic cross-sectional views illustrating a method for fabricating an electronic package 3 according to a second embodiment of the present disclosure. The present embodiment differs from the first embodiment in the process sequence of the conductors 25, and the same processes will not be repeated below.

Referring to FIG. 3A, a plurality of conductors 35 are formed on the electrode pads 210 of the electronic element 21. Then, the active surface 21b of the electronic element 21 is disposed on the release layer 200 of the carrier 20 with the conductors 35 partially or completely embedded in the release layer 200.

Referring to FIG. 3B, continuing the processes of FIG. 2B to FIG. 2C, an encapsulant 22 is formed to encapsulate the electronic element 21 and the conductors 35, and the carrier 20 and the release layer 200 are removed to expose the first surface 22a of the encapsulant 22 and the conductors 35. As such, the conductors 35 partially or completely protrude from the first surface 22a of the encapsulant 22.

Referring to FIG. 3C, continuing the processes of FIGS. 2D to 2G, a dielectric layer 24 and a circuit layer 23 are formed on the first surface 22a of the encapsulant 22, an insulating protection layer 28 and a plurality of conductive elements 27 are formed on the dielectric layer 24 and the circuit layer 23, and a singulation process is performed to obtain the electronic package 3.

According to the method of the present disclosure, through the design of the conductors 35 having a width greater than that of the electrode pads 210, when the electronic element 21 and the circuit layer 23 deviate in position relative to one another, the circuit layer 23 will be still in contact with the conductors 35 and electrically connected to the electronic element 21. Compared with the prior art, the method of the present disclosure can prevent the problem of poor electrical connection of the electronic package due to deviation of the electronic element 21 (i.e., poor electrical connection between the circuit layer 23 and the electrode pads 210 of the electronic element 21), thus preventing final product failure or scrapping.

Further, by controlling the layout area of the conductors 35, the present disclosure can also prevent the problem of poor electrical connection due to deviation of the electronic element 21.

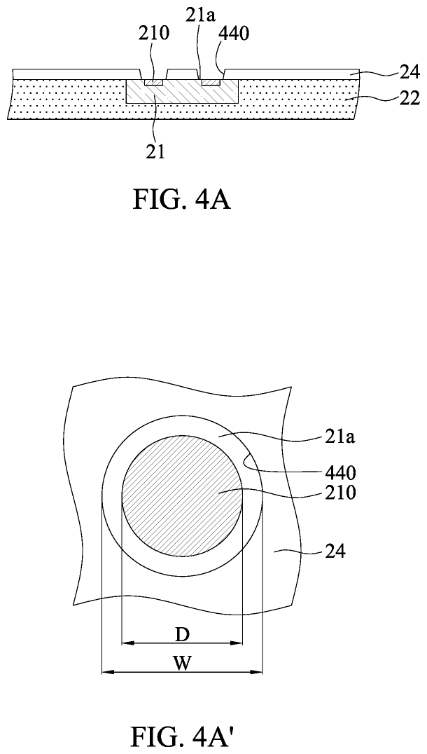

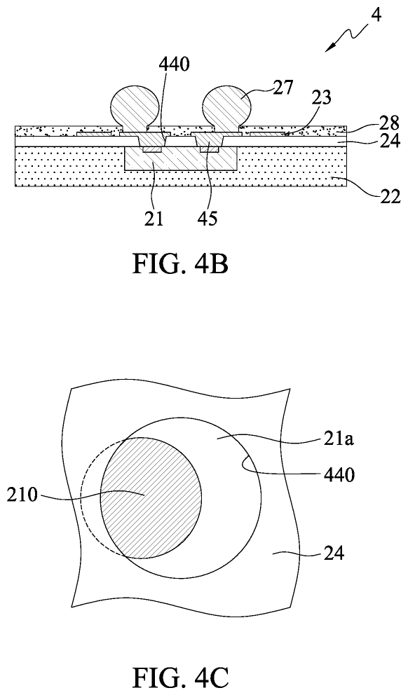

FIGS. 4A to 4B are schematic cross-sectional views illustrating a method for fabricating an electronic package 4 according to a third embodiment of the present disclosure. The present embodiment differs from the first embodiment in the process of the openings of the dielectric layer, and the same processes will not be repeated below.

Referring to FIG. 4A, in the process of FIG. 2D, a plurality of openings 440 are formed in the dielectric layer 24 corresponding to the electrode pads 210.

In an embodiment, the width W of the openings 440 is greater than the width D of the electrode pads 210. As such, referring to FIG. 4A′, the electrode pad 210 and the active surface 21a around the electrode pad 210 are exposed from the opening 440.

Referring to FIG. 4B, continuing the processes of FIGS. 2F to 2G, a circuit layer 23 is formed on the dielectric layer 24 and a plurality of conductors 45 are formed in the openings 440. The circuit layer 23 and the conductors 45 are integrally formed. Thereafter, an insulating protection layer 28 and a plurality of conductive elements 27 are formed on the encapsulant 22 and the circuit layer 23, and a singulation process is performed to obtain the electronic package 4.

In an embodiment, the circuit layer 23 and the conductors 45 are integrally formed to save the fabrication time and cost.

According to the method of the present disclosure, by forming the openings 440 with a relatively large width in the dielectric layer 24 (i.e., by increasing the width W of the openings 440 or the layout area of the conductors 45), when the openings 440 and the electrode pads 210 deviate in position relative to one another, as shown in FIG. 4C, the electrode pads 210 will be still partially exposed from the openings 440 so as for the conductors 45 to be in contact with the electrode pads 210. Therefore, the circuit layer 23 can be electrically connected to the electronic element 21. Compared with the prior art, the method of the present disclosure can prevent the problem of poor electrical connection due to deviation in exposure and development of a patterned photoresist used for fabricating the circuit layer 23, thus preventing final product failure or scrapping.

Further, by increasing the layout area of the conductors 45, the present disclosure can also prevent the problem of poor electrical connection due to deviation of the electronic element 21.

The present disclosure further provides an electronic package 2, 2′, 3, 4, which comprises: an encapsulant 22, an electronic element 21, at least one conductor 25, 35, 45 and a circuit layer 23.

The encapsulant 22 has a first surface 22a and a second surface 22b opposite to the first surface 22a.

The electronic element 21 is embedded in the encapsulant 22 and has a plurality of electrode pads 210 exposed from the first surface 22a of the encapsulant 22.

The conductor 25, 35, 45 is formed on and electrically connected to at least one of the electrode pads 210, wherein the conductor 25, 35, 45 has a metal structure.

The circuit layer 23 is formed on the first surface 22a of the encapsulant 22 and in contact with the conductor 25, 35, 45.

In an embodiment, the electronic element 21 has a passivation layer 211, which has a plurality of open regions 212 exposing the plurality of electrode pads 210. For example, the distance t between an outermost edge of the layout area of the conductor 25, 35 and an edge of the corresponding open region 212 is greater than or equal to 10 μm.

In an embodiment, the layout area (e.g., width R) of the conductor 25, 35, 45 is greater than that of the electrode pad 210 (e.g., width D).

In an embodiment, the conductor 25, 35 comprises first, second and third metal layers 251, 252, 253.

In an embodiment, the layout area (e.g., length L) of the circuit layer 23 is greater than the layout area (e.g., width R) of the conductor 25, 35, 45.

In an embodiment, the conductor 35 is buried in the encapsulant 22.

In an embodiment, the electronic package 2, 2′, 4 further comprises a dielectric layer 24 formed on the first surface 22a of the encapsulant 22, and the conductor 25, 45 is buried in the dielectric layer 24. For example, the dielectric layer 24 has at least one opening 440 and the width W of the opening 440 is greater than the width D of the electrode pad 210.

In an embodiment, the circuit layer 23 and the conductor 45 are integrally formed.

In an embodiment, the electronic package 2, 2′, 3, 4 further comprises a plurality of conductive elements 27 formed on and electrically connected to the circuit layer 23.

In an embodiment, the electronic package 2′ further comprises a circuit structure 26 formed on the first surface 22a of the encapsulant 22 and the circuit layer 23, and the circuit structure 26 is electrically connected to the circuit layer 23.

According to the present disclosure, through the design of the conductor, when the electronic element deviates in position, the circuit layer will be still in contact with the conductor and hence electrically connected to the electronic element. Therefore, the present disclosure can prevent the problem of poor electrical connection due to deviation of the electronic element, thus preventing final product failure or scrapping.

The above-described descriptions of the detailed embodiments are to illustrate the preferred implementation according to the present disclosure, and it is not to limit the scope of the present disclosure. Accordingly, all modifications and variations completed by those with ordinary skill in the art should fall within the scope of present disclosure defined by the appended claims

What is claimed is:

1. An electronic package, comprising:
an encapsulant;
an electronic element embedded in the encapsulant and having a plurality of electrode pads;
at least a conductor formed on and electrically connected to at least one of the electrode pads, wherein the conductor has a metal structure; and
a circuit layer formed on the encapsulant and in contact with the conductor.

2. The electronic package of claim 1, wherein the electronic element has a passivation layer having a plurality of open regions exposing the electrode pads, and wherein a distance between an outermost edge of a layout area of the conductor and an edge of the corresponding open region is greater than or equal to 10 μm.

3. The electronic package of claim 1, wherein a layout area of the conductor is greater than a layout area of the electrode pad.

4. The electronic package of claim 1, wherein the conductor comprises a plurality of metal layers.

5. The electronic package of claim 1, wherein a layout area of the circuit layer is greater than a layout area of the conductor.

6. The electronic package of claim 1, wherein the conductor is buried in the encapsulant.

7. The electronic package of claim 1, further comprising a dielectric layer formed on the encapsulant, wherein the conductor is buried in the dielectric layer, and wherein the dielectric layer has an opening having a width greater than a width of the electrode pad.

8. The electronic package of claim 1, wherein the circuit layer and the conductor are integrally formed.

9. The electronic package of claim 1, further comprising a plurality of conductive elements formed on and electrically connected to the circuit layer.

10. The electronic package of claim 1, further comprising a circuit structure formed on the encapsulant and the circuit layer and electrically connected to the circuit layer.

11. A method for fabricating an electronic package, comprising:
providing at least one electronic element having a plurality of electrode pads;
encapsulating the electronic element with an encapsulant and forming at least one conductor on at least one of the electrode pads, wherein the conductor has a metal structure and is electrically connected to the electrode pad; and
forming a circuit layer on the encapsulant, wherein the circuit layer is in contact with the conductor.

12. The method of claim 11, wherein the electronic element has a passivation layer having a plurality of open regions exposing the electrode pads, and wherein a distance between an outermost edge of a layout area of the conductor and an edge of the corresponding open region is greater than or equal to 10 μm.

13. The method of claim 11, wherein a layout area of the conductor is greater than a layout area of the electrode pad.

14. The method of claim 11, wherein the conductor comprises a plurality of metal layers.

15. The method of claim 11, wherein a layout area of the circuit layer is greater than a layout area of the conductor.

16. The method of claim 11, wherein forming the conductor comprises:
forming the conductor on the electrode pad; and
then simultaneously encapsulating the electronic element and the conductor with the encapsulant.

17. The method of claim 11, wherein forming the conductor comprises:
forming a dielectric layer on the encapsulant;
forming an opening in the dielectric layer for exposing the electrode pad; and
forming the conductor in the opening, wherein the conductor is in contact with the electrode pad, and wherein the opening has a width greater than a width of the electrode pad.

18. The method of claim 11, wherein the circuit layer and the conductor are integrally formed.

19. The method of claim 11, further comprising forming a plurality of conductive elements on the circuit layer, wherein the conductive elements are electrically connected to the circuit layer.

20. The method of claim 11, further comprising forming a circuit structure on the encapsulant and the circuit layer, wherein the circuit structure is electrically connected to the circuit layer.
